(19) United States
(12) Patent Application Publication
(10) Pub. No.: US 2004/0188593 A1
(43) Pub. Date: Sep. 30, 2004

(54) Photosensor control unit

(76) Inventors: Patrick Mullins, San Diego, CA (US); Steven A. Wright, La Jolla, CA (US)

Correspondence Address: LAW OFFICES OF ERIC KARICH, 2807 ST. MARK DR., MANSFIELD, TX, 76063, US

(21) Appl. No.: 10/822,537

(22) Filed: Apr. 12, 2004

Related U.S. Application Data
(63) Continuation-in-part of application No. 10/805,969, filed on Mar. 22, 2004, now abandoned.
(60) Provisional application No. 60/456,111, filed on Mar. 20, 2003.

(51) Int. Cl. H01L 27/15; H05B 37/02; G01J 3/50

(52) U.S. Cl. 250/205; 250/214 AL; 315/156; 250/226

(57) ABSTRACT

A photosensor control unit for use in a lighting module has a plurality of LEDs, a light sensor, and a switch adapted to operably control the plurality of LEDs responsive to the light sensor. The plurality of LEDs are adapted to be mounted in the lighting module, and are configured to produce light having wavelengths within a first range of wavelengths. The light sensor is adapted to be mounted in the lighting module adjacent the plurality of LEDs, and is responsive to light having wavelengths within a second range of wavelengths. The second range of wavelengths is exclusive of the first range of wavelengths. The switch is adapted to operably control the plurality of LEDs responsive to the light sensor such that the plurality of LEDs emit light having wavelengths within the first range of wavelengths responsive to the presence or absence of light within the second range of wavelengths.

### CROSS-REFERENCE TO RELATED APPLICATIONS

This application for a utility patent claims the benefit of U.S. Provisional Application No. 60/456,111, filed Mar. 20, 2003 and U.S. Utility application Ser. No. 10/805,969, filed Mar. 22, 2004. This application is incorporated herein by reference in its entirety.

### STATEMENT REGARDING FEDERALLY SPONSORED RESEARCH

Not Applicable

### BACKGROUND OF THE INVENTION

1. Field of the Invention

This invention relates generally to photosensor control units, and more particularly to a photosensor control unit adapted to be used with an outdoor lighting system wherein a light sensor is positioned within the lighting system adjacent a plurality of LEDs of the lighting system.

2. Description of Related Art

Outdoor lighting systems are commonly used to illuminate selected areas at night. Light sources of outdoor lighting systems are typically turned on in response to low ambient light conditions (e.g., after sunset) and turned off during high ambient light conditions (e.g., during daylight hours). Many outdoor lighting systems with automatic on-off control systems responsive to ambient light conditions include photoconductive cells (i.e., photocells).

Known outdoor lighting fixtures with automatic on-off control include photocells sensitive to visible light. Such photocells cannot distinguish between ambient light and light produced by the lighting fixtures. In order to prevent the photocells from being influenced (e.g., triggered) by the light produced by the lighting fixtures, the photocells must be oriented (i.e., aimed) away from the light exiting the lighting fixtures. As a result, the photocells are often positioned in locations where they are subject to harmful conditions.

For example, known street lighting fixtures have photo-controls positioned on upper surfaces of housings. The photo-controls are subjected to direct sunlight all day long. Sunlight includes destructive ultraviolet radiation, and solar heating causes the components of the photo-controls to be heated to temperatures in excess of 85 degrees Celsius. In addition, the upper surface mounting of the photo-controls also subjects the photo-controls to harsh weather, debris from trees, and bird droppings. The debris from trees and bird droppings can obscure plastic windows through which light passes, shading internal photocells from the ambient light and causing the street lighting fixtures to operate for longer hours. These and other exposure conditions often eventually lead to failure or unpredictable performance of the photo-controls and/or the street lighting fixtures. Furthermore, top side socket mounted photo control units frequently leak water into the fixture, which can cause internal failures.

It would be advantageous to have a lighting assembly with automatic on-off control that does not include a photo-control positioned on an upper surface of the lighting assembly.

### SUMMARY OF THE INVENTION

The present invention teaches certain benefits in construction and use which give rise to the objectives described below.

The present invention provides a photosensor control unit for use in a lighting module. The photosensor control unit includes a plurality of LEDs, a light sensor, and a switch adapted to operably control the plurality of LEDs responsive to the light sensor. The plurality of LEDs are adapted to be mounted in the lighting module, and are configured to produce light having wavelengths within a first range of wavelengths. The light sensor is adapted to be mounted in the lighting module adjacent the plurality of LEDs, and is responsive to light having wavelengths within a second range of wavelengths. The second range of wavelengths is exclusive of the first range of wavelengths. The switch is adapted to operably control the plurality of LEDs responsive to the light sensor such that the plurality of LEDs emit light having wavelengths within the first range of wavelengths responsive to the presence or absence of light within the second range of wavelengths.

A primary objective of the present invention is to provide a photosensor control unit having advantages not taught by the prior art.

Another objective is to provide a photosensor control unit that includes a light sensor that can be mounted adjacent a plurality of LEDs within a lighting module.

Another objective is to provide a photosensor control unit wherein the plurality of LEDs and the light sensor are mounted on the underside of a housing of the lighting module so that the LEDs direct light in a first direction, and the light sensor is directed to receive light from a second direction that is substantially opposite of the first direction.

A further objective is to provide a photosensor control unit wherein the plurality of LEDs are configured to produce light having wavelengths within a first range of wavelengths, while the light sensor is configured

is not confused mislead by light emitted from the plurality of LEDs.

Other features and advantages of the present invention will become apparent from the following more detailed description, taken in conjunction with the accompanying drawings, which illustrate, by way of example, the principles of the invention.

### BRIEF DESCRIPTION OF THE DRAWING

The accompanying drawings illustrate the present invention. In such drawings:

FIG. 1 is a side elevation view of one embodiment of a lighting module that includes a photosensor control unit, the lighting module being attached to a vertical light pole via a horizontally extending arm, wherein the lighting modules includes a circuit board mounted within a housing;

FIG. 2 is a perspective view of an underside portion of the lighting module of FIG. 1;

FIG. 3 is a diagram of one embodiment of the photosensor control unit of FIGS. 1 and 2;

FIG. 4 is a side elevation view of a portion of the lighting module and the photosensor control unit of FIG. 3 wherein the lighting module is oriented to illuminate a target surface;

FIG. 5 is a side elevation view of a typical prior art street lighting fixture;

FIG. 6 is a graph of light intensity versus wavelength at the lighting module of FIGS. 1 and 2 during daylight hours;

FIG. 7 is a graph of light intensity versus wavelength at the lighting module of FIGS. 1 and 2 at sunset; and

FIG. 8 is a perspective view of a portion of one embodiment of the circuit board of FIGS. 1 and 2; and

FIG. 9 is a sectional view thereof taken along line 9-9 in FIG. 8, wherein the circuit board is in contact with the inner surface of the housing of FIGS. 1 and 2.

### DETAILED DESCRIPTION OF THE INVENTION

FIG. 1 is a side elevation view of one embodiment of a lighting module 10 that includes a photosensor control unit 11. In this embodiment, the lighting module 10 is attached to a vertical light pole 12 via a horizontally extending arm 14, and includes a plurality of light-emitting diodes (LEDs) 28 within a protective housing 20. In this embodiment, the housing includes a top surface 22 and an inner surface 24 that extends to a perimeter 25.

The photosensor control unit 11 of this embodiment includes a control unit 18 operably connected to a light sensor 26 for operably controlling the plurality of LEDs 28. In general, the control unit 18 receives a signal from the light sensor 26 and controls a supply of electrical power to the LEDs 28 dependent upon the signal.

In the present embodiment, the plurality of LEDs 28 are mounted on a circuit board 16 that is mounted within the protective housing 20, and the light sensor 26 is mounted adjacent the plurality of LEDs 28. In this embodiment, the circuit board 16 has two opposed major surfaces. Mounted within the housing 20, one of the two major surfaces of the circuit board 16 is adjacent the inner surface 24 of the housing 20. In this embodiment, the sensor 26 and the plurality of LEDs 28 are mounted to the other major surface of the circuit board 16, which is described in greater detail below.

While one embodiment is described in detail herein, those skilled in the art will recognize that many alternative embodiments are also suitable for the present invention. Many different circuitboard designs could be used, and it is also possible that the plurality of LEDs 28 and/or the light sensor 26 could be mounted in other manners. While we specify that the light sensor 26 and the plurality of LEDs 28 are adjacent each other, this should be construed broadly. For example, the sensor 26 and the plurality of LEDs 28 could be independent components that are positioned separately within the housing 20, as long as they are directed towards a common target surface 122 (shown in FIG. 4), as described below. Alternative embodiments that can be devised by those skilled in the art, consistent with the teachings of this disclosure, should be considered within the scope of the claimed invention.

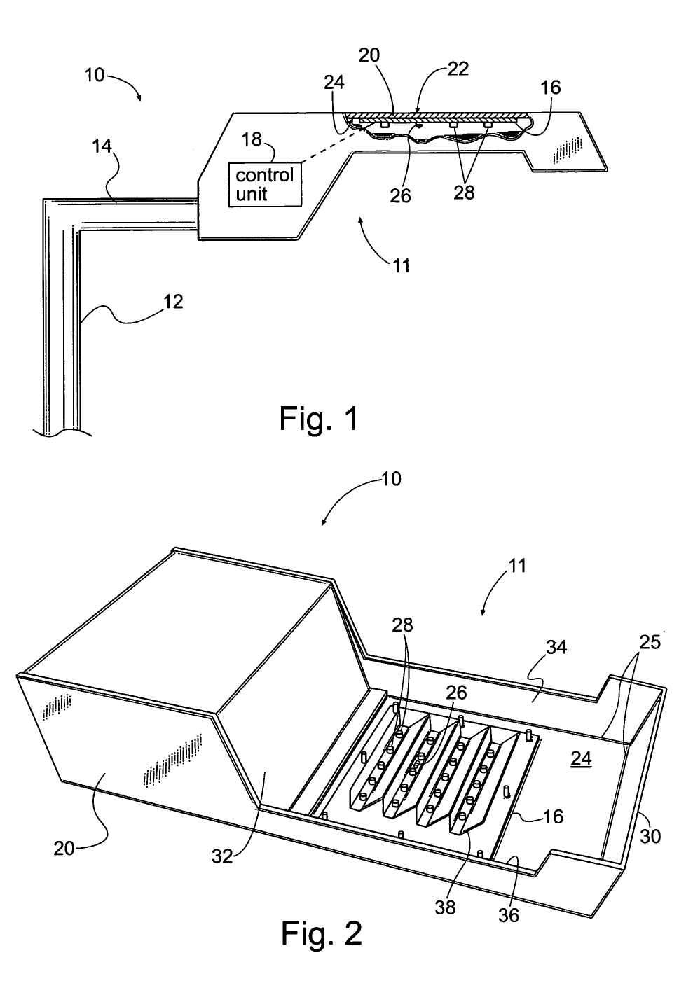

FIG. 2 is a perspective view of an underside portion of the lighting module 10 of FIG. 1. In the embodiment of FIG. 2 the circuit board 16 is mounted to the inner surface 24 of the housing 20 as described above. The housing 20 includes a downwardly extending sidewall that extends downwardly from the perimeter 25 of the inner surface 24 of the housing 20. In the present embodiment, the downwardly extending sidewall includes four sidewalls that surround the circuit board 16: a front sidewall 30, a rear sidewall 32, and two side sidewalls 34 and 36. When the lighting module 10 is oriented as shown in FIG. 1, the sidewalls 30, 32, 34, and 36 extend downwardly from the perimeter 25 of the inner surface 24 of the housing 20.

In the embodiment of FIG. 2, the LEDs 28 are arranged within a reflector assembly 38 that reflects a portion of the light emitted by the LEDs 28. The reflector assembly 38 is configured such that the light emitted by the LEDs 28 produces the desired illumination pattern on the target surface.

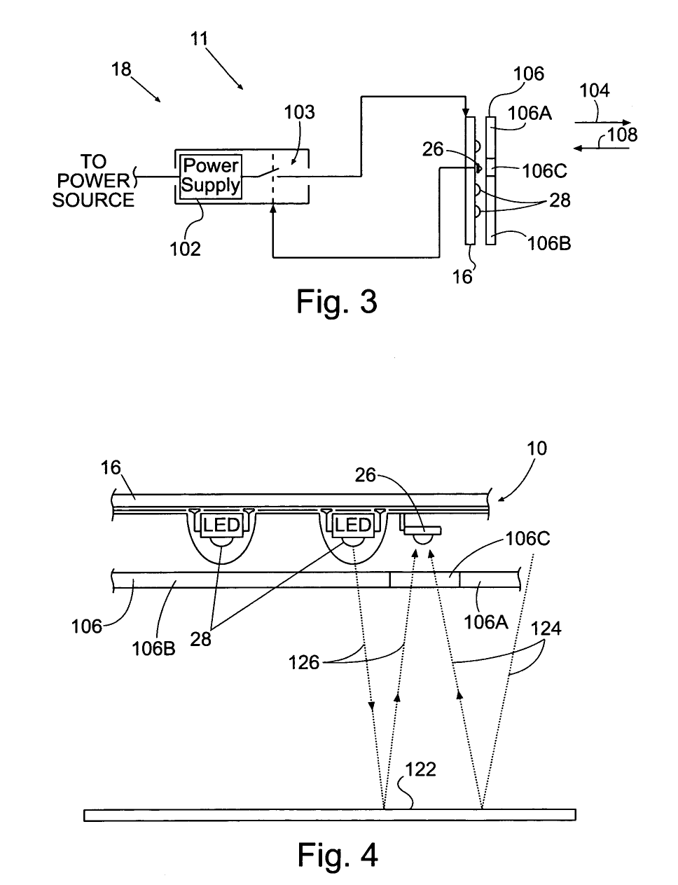

FIG. 3 is a diagram of one embodiment of the lighting module 10 and the photosensor control unit 11. In this embodiment, the control unit 18 is coupled to the array of LEDs 28 and the light sensor 26. The control unit 18 includes a power supply 102 and a switch 103. The power supply 102 receives electrical power from a source of electrical power and producing conditioned electrical power for the LEDs 28. The control unit applies conditioned electrical power from the power supply 102 to the LEDs 28 via the switch 103. When the conditioned electrical power is applied to the LEDs 28, the LEDs 28 produce light having wavelengths within a first range of wavelengths, wherein the first range of wavelengths is within the visible light spectrum. The LEDs 28 are arranged to emit light substantially in a first direction 104.

LEDs are diodes that emit light when electrical current passes through them. LEDs are in general more efficient, last longer, operate at cooler temperatures, and are more durable than many other known types of light sources. Also, unlike many other known types of light sources, LEDs emit light within relatively narrow frequency ranges.

The conditioned electrical power produced by the power supply 102 includes an electrical voltage and current. In general, the power supply 102 controls the voltage and/or the current to meet electrical power requirements of the LEDs 28. For example, the LEDs 28 may require a substantially constant electrical current. In this situation, the power supply 102 may control the voltage of the conditioned electrical power such that current of the conditioned electrical power is substantially constant.

The visible light spectrum includes light having wavelengths between about 380 nanometers (nm) and approximately 740 nm. The LEDs 28 may include, for example, LEDs producing white, red, green, or blue light, or a combination thereof. In general, LEDs producing white light emit light having wavelengths between about 430 nm and approximately 660 nm. LEDs producing red light emit light having wavelengths between about 630 nm and approximately 660 nm. LEDs producing green light emit light having wavelengths between about 520 nm and approximately 570 nm, and LEDs producing blue light emit light having wavelengths between about 430 nm and approximately 470 nm.

A lens 106 is positioned adjacent to the LEDs 28 in the direction 104. Portions 106A and 106B of the lens 106 are substantially transparent to the light emitted by the LEDs 28. The portions 106A and 106B distribute the light emitted by the LEDs 28 substantially in the first direction 104 and to achieve the desired illumination pattern on the target surface.

The light sensor 26 may be positioned within the arranged LEDs 28 and is responsive to light having wavelengths within a second range of wavelengths, wherein the second range of wavelengths is not within the visible light spectrum. The second range of wavelengths may be, for example, within the near-infrared spectrum or the ultraviolet spectrum. The light sensor 26 is oriented to receive light originating substantially from a second direction 108 and via a portion 106C of the lens 106. The second direction 108 is substantially opposite the first direction 104 in which the portions 106A and 106B of the lens 106 distribute the light emitted by the LEDs 28.

While we specify that the second direction 108 is substantially opposite the first direction 104, the should not be narrowly construed. The second direction 108 is intended to encompass a range of light from a target surface 122, as shown in FIG. 4

The portion 106C of the lens 106 is substantially transparent to the light within the second range of wavelengths to which the light sensor 26 is responsive. The portion 106C of the lens 106 functions to optically focus the light sensor 26 to receive light from the second direction 108, as described in greater detail below.

In addition to the lens 106, the housing 20, as described above, also functions to direct the light sensor 26 towards the second direction 108. In particular, the downwardly extending sidewalls (shown in FIGS. 1 and 2) function to shield the light sensor 26 so that it receives light primarily from the second direction 108.

The near-infrared light spectrum includes light having wavelengths between about 750 nm and approximately 1 millimeter, and the ultraviolet light spectrum includes light having wavelengths between about 10 nm and approximately 380 nm. The light sensor 26 may be, for example, a phototransistor responsive to light in the near-infrared light spectrum, or a photodiode responsive to light in the ultraviolet light spectrum.

The light sensor 26 produces a signal indicative of an amount of light within the second range of wavelengths received by the light sensor 26. The control unit 18 receives the signal from the light sensor 26 and provides the conditioned electrical power produced by the power supply 102 to the LEDs 28 dependent upon the signal. For example, the signal produced by the light sensor 26 may have a magnitude indicative of the amount of light within the second range of wavelengths received by the light sensor 26. The control unit 18 may provide the conditioned electrical power to the LEDs 28 when the magnitude of the signal is less than a threshold value, and may interrupt the supply of conditioned electrical power to the LEDs 28 when the magnitude of the signal is greater than or equal to the threshold value.

FIG. 4 is a side elevation view of the lighting module 10, illustrating how the lighting module 10 is oriented to illuminate a target surface 122. Light 126 produced by the LEDs 28 illuminates the target surface 122. The target surface 122 may be, for example, a portion of a street or a sidewalk.

Ambient light from the sun (i.e., daylight), represented by rays 124, is reflected from the target surface 122 and received by the light sensor 26 via the portion 106C of the lens 106. The portion 106C of the lens 106 functions to optically focus the light sensor 26 to receive light from the second direction 108, from the target surface 122.

In general, the ambient daylight includes the second range of wavelengths to which the sensor 26 is responsive. As a result, the control unit 18 of FIG. 3 may provide the conditioned electrical power to the LEDs 28 when a level of the ambient daylight is less than a threshold value, and may interrupt the supply of conditioned electrical power to the LEDs 28 a level of the ambient daylight is greater than or equal to the threshold value.

A portion of the light produced by the LEDs 28, represented by rays 126, is also reflected from the target and received by the portion 106C of the lens 106. The portion 106C of the lens 106 may, for example, partially or totally block the light within the first range of wavelengths produced by the LEDs 28. Alternately, or in addition, the sensor 26 may respond to the first range of wavelengths produced by the LEDs 28 to a lesser extent than the first range of wavelengths. In any case, the signal produced by the light sensor 26 is preferably largely independent of any amount of light within the first range of wavelengths received by the light sensor 26 via the portion 106C of the lens 106.

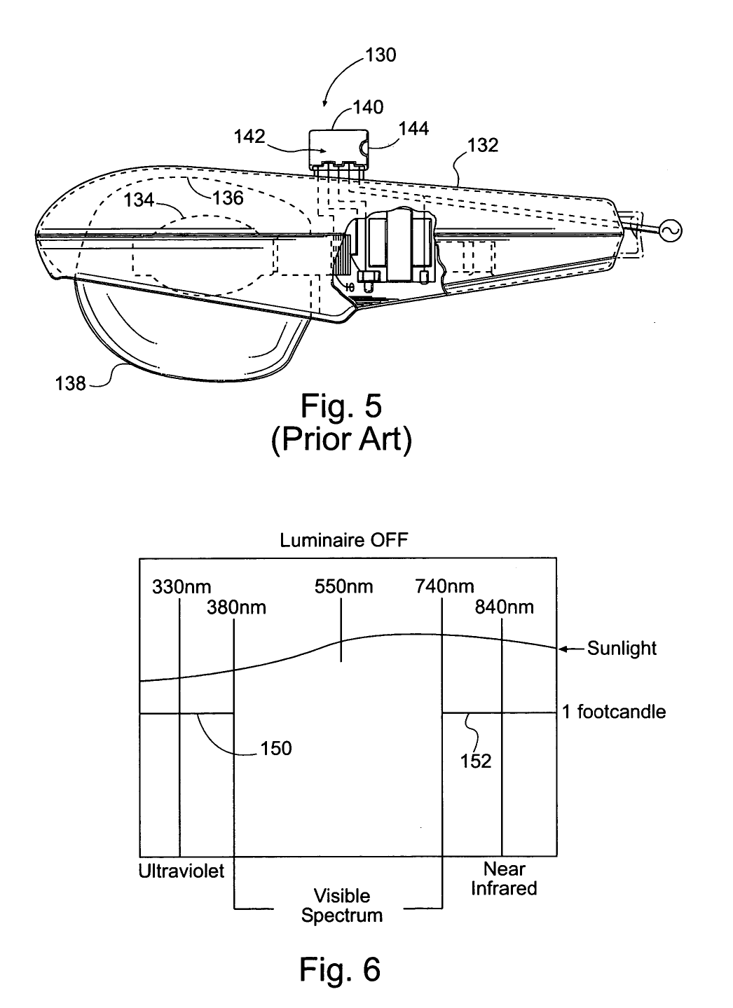

FIG. 5 is a side elevation view of a typical prior art street lighting fixture 130. (See U.S. Pat. No. 3,949,211 to Elms.) The prior art street lighting fixture 130 includes a fixture body 132 housing a light source 134. Light emitted by the light source 134 exits the fixture body 132 in a downward direction via a reflector 136 and a diffuser 138. A photocontrol 140 including a photocell is mounted in an opaque housing 142 on an upper surface of the fixture body 132. The opaque housing 142 has a plastic window 144 in a side surface that is substantially transparent to visible light. Ambient light entering the housing 142 via the plastic window 144 strikes the photocell of the photocontrol 140. In response to a signal from the photocell, the photocontrol 140 applies electrical power to the light source 134 during low ambient light conditions (e.g., after sunset) and interrupts the supply of electrical power during high ambient light conditions (e.g., during daylight hours).

As is typical, the photocell of the photocontrol 140 is sensitive to visible light and cannot distinguish between ambient light and the light emitted by the light source 134. In order to prevent the photocell from being influenced (e.g., triggered) by the light emitted by the light source 134, the plastic window 144 of the housing 142 is oriented (i.e., aimed) away from the light exiting the fixture housing 132 such that the photocell does not receive light emitted by the light source 134.

A problem arises in that, positioned on the upper surface of the fixture housing 132, the photocontrol 140 is exposed to several harmful conditions. First of all, the photocontrol 140 is subjected to direct sunlight all day long. Sunlight includes destructive ultraviolet radiation, and solar heating causes the components of the photocontrol 140 to be heated to temperatures in excess of 85 degrees Celsius. In addition, the upper surface mounting of the photocontrol 140 also subjects the photocontrol 140 to harsh weather, debris from trees, and bird droppings. The debris from trees and bird droppings can obscure the plastic window 144, shading the photocell of the photocontrol 140 from the ambient light and causing the luminaire to operate for longer hours. Further, a conventional photocell is typically mounted atop a fixture housing via a plug in connector fitting arrangement to facilitate replacement. This fitting arrangement can and often does leak during rainy weather, allowing rain water to enter the fixture housing and hasten electrical connection corrosion and failure. The above exposure conditions often eventually lead to failure or unpredictable performance of the photocontrol 140 and/or the prior art street lighting fixture 130.

FIG. 6 is a graph of light intensity versus wavelength at the lighting module 10 of FIGS. 1 and 2 during daylight hours. In general, the light sensor 26 may be responsive to light within the near-infrared spectrum and/or the ultraviolet spectrum. In FIG. 6 a first exemplary threshold level 150 is shown for the near-infrared spectrum and a second exemplary threshold level 152 is shown for the ultraviolet spectrum. For convenience, the exemplary threshold levels 150 and 152 are both representative of 1 foot candle.

In FIG. 6, the magnitude of the signal produced by the light sensor 26 in the ultraviolet case is greater than the threshold level 150. In response, the control unit 18 (FIGS. 1 and 3) may interrupt the supply of conditioned electrical power from the power supply 102 (FIG. 3) to the LEDs 28 (FIGS. 1-2) and in this situation the lighting module 10 of FIGS. 1 and 2 is off. Similarly, the magnitude of the signal produced by the light sensor 26 in the near-infrared case is greater than the threshold level 152. The control unit 18 may interrupt the supply of conditioned electrical power from the power supply 102 to the LEDs 28, and the lighting module 10 may again be off.

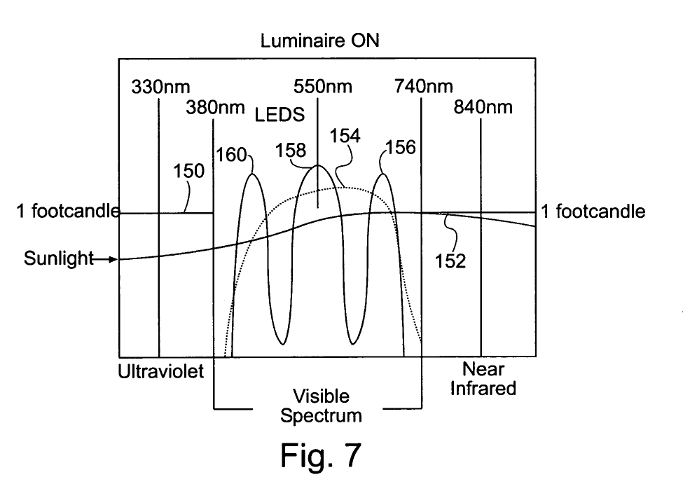

FIG. 7 is a graph of light intensity versus wavelength at the lighting module 10 of FIGS. 1 and 2 at sunset. In FIG. 7, the magnitude of the signal produced by the light sensor 26 in the ultraviolet case is less than the threshold level 150. In response, the control unit 18 (FIGS. 1 and 3) may provide the conditioned electrical power from the power supply 102 (FIG. 5) to the LEDs 28 (FIGS. 1-2), and in this situation the lighting module 10 of FIGS. 1 and 2 is on. Similarly, the magnitude of the signal produced by the light sensor 26 in the near-infrared case is less than the threshold level 152. The control unit 18 may provide the conditioned electrical power from the power supply 102 to the LEDs 28, and the lighting module 10 may again be on.

As described above, the LEDs 28 (FIGS. 1-2) may include LEDs producing white, red, green, or blue light, or a combination thereof. In FIG. 7 a curve 154 represents white light produced by some or all of the LEDs 28, a curve 156 represents red light produced by some or all of the LEDs 28, a curve 158 represents green light produced by some or all of the LEDs 28, and a curve 160 represents blue light produced by some or all of the LEDs 28. It is noted that in all cases the light produced by the LEDs 28 is within the visible light spectrum.

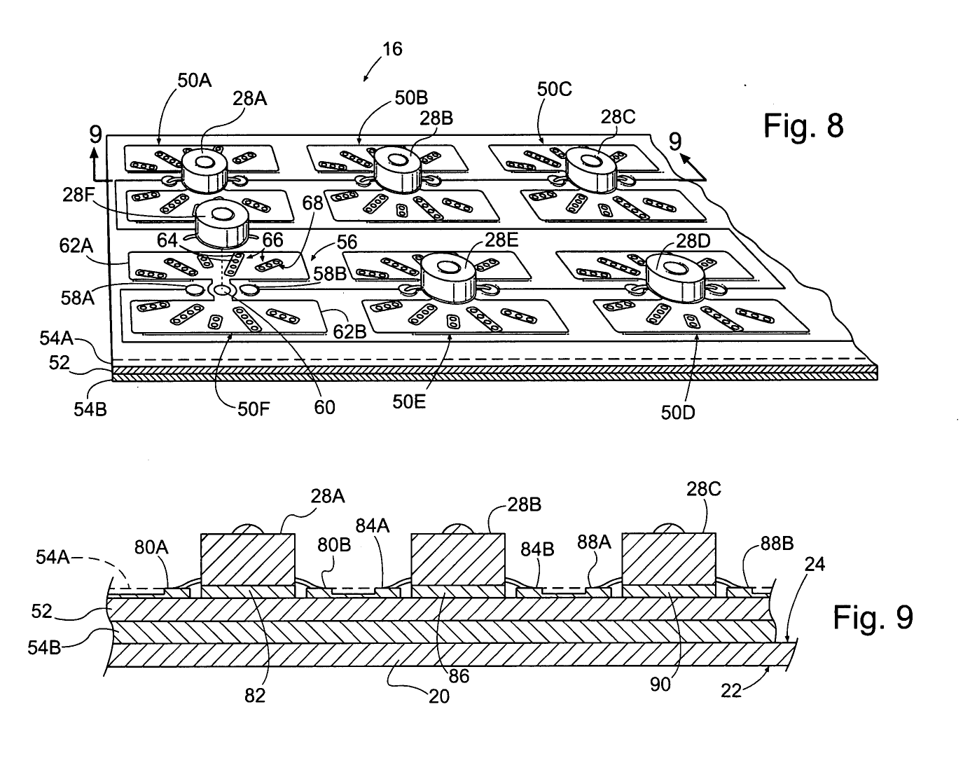

FIG. 8 is a perspective view of a portion of one embodiment of the circuit board 16 of FIGS. 1 and 2. In this embodiment, the portion of the circuit board 16 includes six structures 50A-50F for mounting six of the LEDs 28 to the circuit board 16. Five LEDs 28A-28E are shown mounted to structures 50A-50E, respectively, and a sixth LED 28F is shown above the structure 50F. The six structures 50A-50F are referred to collectively as the structures 12.

In this embodiment, the circuit board 16 includes an electrically insulating base material 52 (e.g., a fiberglass-epoxy composite base material) having two opposed sides. Electrically conductive layers 54A and 54B (e.g., metal layers such as copper layers) exist on each of the two opposed sides of the base material 52.

In this embodiment, portions of the electrically conductive layer 54A have been removed from the circuit board 16 to form the features of the structures 50A-50F. That is, a subtractive process has been used to form the features of the structures 50A-50F in the initially continuous electrically conductive layer 50A. It is noted that the features of the structures 50A-50F may also be formed using an additive process.

In this embodiment, the structure 50F, typical of each of the structures 50, includes a heat dissipating structure 56 and a pair of electrical lead pads 58A and 58B positioned adjacent to the heat dissipating structure 56. The heat dissipating structure 56 includes a centrally located LED thermal pad 60 and a pair of heat dissipation regions 62A and 62B extending from an upper side and a lower side, respectively, of the LED thermal pad 60. The pair of electrical lead pads 58A and 58B are positioned on a left side and a right side, respectively, of the LED thermal pad 60. The LED thermal pad 60 is adapted to contact an underside surface of one of the LEDs 24 when the LED is mounted on the pair of electrical lead pads 58A and 58B.

In this embodiment, the electrically conductive layers 54A and 54B of the circuit board 16 are layers of a metal such as copper. As a result, the LED thermal pad 60, the heat dissipation regions 62A and 62B, and the electrical lead pads 58A and 58B are all made of the metal, and the heat dissipation regions 62A and 62B extending from the LED thermal pad 60 are both electrically and thermally coupled to LED thermal pad 60.

As the structure 50F is typical of each of the structures 50, each of the structures 50 has a pair of heat dissipation regions similar to 62A and 62B, referred to collectively as heat dissipation regions 62, extending from an LED thermal pad 60. The LED thermal pad 60 and the heat dissipation regions 62 are thermally coupled to the electrically conductive layer 54B on the opposite side of the circuit board 16 via the base material 52 of the circuit board 16.

In one embodiment, the heat dissipation regions 62 each have a surface area (in contact with the base material 52 of the circuit board 16) that is at least twice the surface area of the LED thermal pad 60. Due to the relatively large areas of the heat dissipation regions 62, the thermal resistance of the thermal path between the LED thermal pad 60 and the electrically conductive layer 54B on the opposite side of the circuit board 16 is advantageously reduced.

In this embodiment, multiple optional plated through holes (i.e., vias) 64 are used to further reduce the thermal resistance of the thermal path between the LED thermal pad 60 and the electrically conductive layer 54B on the opposite side of the circuit board 16. In this embodiment, five spokes 66 exist in different portions of the heat dissipation region 62A. As shown in FIG. 8, the portions of the heat dissipation region 62A in which the spokes 66 exist are oriented along lines extending radially outward from a center of the thermal pad 60. The vias 64 connect each of the portions of the heat dissipation region 62A in which the spokes 66 exist to the electrically conductive layer 54B on the opposite side of the circuit board 16. In the embodiment of FIG. 3, the vias 64 of each of the spokes 66 are arranged along the corresponding line extending radially outward from the center of the thermal pad 60. A similar set of 5 spokes exist in different portions of the heat dissipation region 62B.

In the embodiment of FIG. 8, each of the portions of the heat dissipation region 62A in which the spokes 66 exist is electrically isolated from a remainder of the heat dissipation region 62A. This electrical isolation is necessary in embodiments where a voltage level impressed on the portions of the electrically conductive layer forming the LED thermal layer 60 and the heat dissipation regions 62A and 62B (e.g., via an LED mounted to the corresponding structure 50) differs from a voltage level impressed on the electrically conductive layer 54B on the opposite sides of the circuit board 16. It is noted that this electrical isolation may not be required in other embodiments.

As the structure 50F is typical of each of the structures 50, each of the structures 50 has a pair of heat dissipation regions 62 extending from an LED thermal pad 60. Each of the heat dissipation regions 62 has 5 spokes in portions of the heat dissipation regions 62 electrically isolated from, but thermally coupled to, remainders of the heat dissipation regions 62. Multiple plated through holes (i.e., vias) 64 connect each of the portions of the heat dissipation regions 62 to the electrically conductive layer 54B on the opposite side of the circuit board 16.

In the preferred embodiment, the electrically conductive layers 54A and 54B of the circuit board 16 are layers of a metal such as copper, and the plated through holes (i.e., vias) 64 are formed from a metal such as copper. Narrow gaps 68 in the portions of the metal layer forming the heat dissipation regions 62 separate the portions of the heat dissipation regions 62 in which the spokes 66 exist from the remainders of the heat dissipation regions 62. The narrow gaps 68 electrically isolate the portions of the heat dissipation regions 62 in which the spokes 66 exist from the remainders of the heat dissipation regions 62. The portions of the heat dissipation regions 62 in which the spokes 66 exist are thermally coupled to the remainders of the heat dissipation regions 62 via the underlying base material of the circuit board 16.

In addition, the narrow gaps 68 may be filled with an electrically insulating material that is also thermally conductive. In this situation, the portions of the heat dissipation regions 62 in which the spokes 66 exist are also thermally coupled to the remainders of the heat dissipation regions 62 via the material filling the narrow gaps 68.

The metal plated through holes (i.e., vias) 64 thermally couple the portions of the heat dissipation regions 62 in which the spokes 66 exist to the electrically conductive layer on the opposite side of the circuit board 16. As a result, the thermal resistance of the thermal path between the LED thermal pad 60 and the electrically conductive layer 54B on the opposite side of the circuit board 16 is advantageously reduced.

As the structure 50F is typical of each of the structures 50, each of the structures 50 has a pair of electrical lead pads 58. In the embodiment of FIG. 8, the electrical lead pads 58 of the structures 50 are connected in series between a pair of electrical connectors by traces or tracks also formed in the electrically conductive layer 54A of the circuit board 16. As a result, all of the LEDs 28 produce light simultaneously when electrical power is applied to the electrical connectors via the control unit 18 of FIG. 1.

While the described circuit board 16 is currently preferred, alternative embodiments of the circuitboard could also be used. For example, any standard circuitboard(s) that are ordinarily used for mounting LEDs could be used in the present invention, and such alternative constructions should be considered within the scope of the claimed invention.

FIG. 9 is a cross-sectional view of a portion of the circuit board 16 of FIG. 8 wherein the circuit board 16 is in contact with the inner surface 24 of the housing 20 of FIGS. 1 and 2. In FIG. 9, the pair of electrical lead pads 58 of the structure 50A (FIG. 8) are labeled 80A and 80B, and the LED thermal pad 60 of the structure 50A (FIG. 8) is labeled 82. The pair of electrical lead pads 58 of the structure 50B (FIG. 8) are labeled 84A and 84B, and the LED thermal pad 60 of the structure 50B (FIG. 8) is labeled 86. The pair of electrical lead pads 58 of the structure 50C (FIG. 8) are labeled 88A and 88B, and LED thermal pad 60 of the structure 50C (FIG. 8) is labeled 90.

In FIG. 9, the leads of the surface mount LED 28A are connected to the pads 80A and 80B, and an underside surface of the LED 28A contacts an upper surface of the LED thermal pad 82. The leads of the surface mount LED 28B are connected to the pads 84A and 84B, and an underside surface of the LED 28B contacts an upper surface of the LED thermal pad 86. Similarly, the leads of the surface mount LED 28C are connected to the pads 88A and 88B, and an underside surface of the LED 28C contacts an upper surface of the LED thermal pad 90.

FIG. 9 also shows the electrically insulating base material 52 of the circuit board 16, the electrically conductive layer 54A in which the electrical lead pads 80A, 80B, 84A, 84B, 88A, and 88B and the LED thermal pads 82, 86, and 90 exist, and the electrically conductive layer 54B on the opposite side of the base material 52.

Portions of the heat energy dissipated by the LEDs 28A-28C during operation are transferred to the LED thermal pads 82, 86, and 90, respectively, via conduction. This heat energy is in turn conducted along the above described thermals path from the LED thermal pads 82, 86, and 90 to the electrically conductive layer 54B on the opposite side of the circuit board 16.

In the embodiment of FIG. 9 the electrically conductive layer 54B is preferably a thermally conductive layer made of copper or similar material that is a good conductor of heat. The thermally conductive layer 54B abuts and is in thermal contact with the inner surface 24 of the housing 20. As a result, heat energy from the thermally conductive layer 54B is conducted through the housing 20 to the top surface 22, where the heat energy is released to the surrounding ambient via conduction and/or radiation. As a result of the conduction of heat away from the LEDs 28A-28F during operation, the operating temperatures of the LEDs 28A-28F are reduced, and the lifetimes of the LEDs 28A-28F are expectedly increased.

While the invention has been described with reference to at least one preferred embodiment, it is to be clearly understood by those skilled in the art that the invention is not limited thereto. Rather, the scope of the invention is to be interpreted only in conjunction with the appended claims.

What is claimed is:

1. A photosensor control unit for use in a lighting module, the photosensor control unit comprising:
a plurality of LEDs adapted to be mounted in the lighting module, the plurality of LEDs being configured to produce light having wavelengths within a first range of wavelengths, wherein the first range of wavelengths is within the visible light spectrum;
a light sensor adapted to be mounted in the lighting module adjacent the plurality of LEDs, the light sensor being responsive to light having wavelengths within a second range of wavelengths, wherein the second range of wavelengths is exclusive of the first range of wavelengths; and
a switch adapted to operably control the plurality of LEDs responsive to the light sensor, whereby the plurality of LEDs emit light having wavelengths within the first range of wavelengths responsive to the presence or absence of light within the second range of wavelengths.

2. The photosensor control unit of claim 1 wherein the plurality of LEDs direct light in a first direction, and wherein the light sensor is positioned to receive light from a second direction, the second direction being substantially opposite the first direction.

3. The photosensor control unit of claim 2 further comprising a lens adapted to be positioned over the light sensor so that a portion of the lens functions to optically focus the light sensor to receive light from the second direction.

4. The photosensor control unit of claim 2 wherein the light sensor and the plurality of LEDs are mounted in a housing having an inner surface extending to a perimeter.

5. The photosensor control unit of claim 4 wherein the housing includes a downwardly extending sidewall extending downwardly from the perimeter, the downwardly extending sidewall functioning to shield the light sensor so that it receives light primarily from the second direction.

6. The photosensor control unit of claim 1 wherein the plurality of LEDs are mounted on a first surface of a circuit board.

7. The photosensor control unit of claim 6 wherein a second surface of the circuit board includes a thermally conductive layer.

8. The photosensor control unit of claim 7 wherein the thermally conductive layer abuts the inner surface of the housing for conducting heat from the plurality of LEDs to the housing.

9. A lighting module comprising:
a housing having an inner surface;
a circuit board having a first surface and a second surface, the circuit board being adapted to be mounted adjacent the inner surface of the housing;
a plurality of LEDs mounted on the first surface of the circuit board, the plurality of LEDs being configured to produce light having wavelengths within a first range of wavelengths, wherein the first range of wavelengths is within the visible light spectrum;
a light sensor adapted to be mounted adjacent the plurality of LEDs, the light sensor being responsive to light having wavelengths within a second range of wavelengths, wherein the second range of wavelengths is exclusive of the first range of wavelengths; and
a switch adapted to be operably connected to the plurality of LEDs and operably controlled by the light sensor, whereby the plurality of LEDs emit light having wavelengths within the first range of wavelengths responsive to the presence or absence of light within the second range of wavelengths.

10. The lighting module of claim 9 wherein the plurality of LEDs direct light in a first direction, and wherein the light sensor is positioned to receive light from a second direction, the second direction being substantially opposite the first direction.

11. The lighting module of claim 10 further comprising a lens adapted to be positioned over the light sensor so that a portion of the lens functions to optically focus the light sensor to receive light from the second direction.

12. The lighting module of claim 10 wherein the light sensor and the plurality of LEDs are mounted in a housing having an inner surface extending to a perimeter.

13. The lighting module of claim 12 wherein the housing includes a downwardly extending sidewall extending downwardly from a perimeter of the inner surface of the housing, the downwardly extending sidewall functioning to shield the light sensor so that it receives light primarily from the second direction.

14. The lighting module of claim 9 wherein the light sensor is mounted on the first surface of the circuit board, adjacent the plurality of LEDs.

15. The lighting module of claim 14 wherein the second surface of the circuit board includes a thermally conductive layer.

16. The lighting module of claim 15 wherein the thermally conductive layer abuts the inner surface of the housing for conducting heat from the plurality of LEDs to the housing.
